(19) United States
(12) Patent Application Publication
(10) Pub. No.: US 2016/0211024 A1
(43) Pub. Date: Jul. 21, 2016

(54) DECODING DATA USING A RESERVED WORD LINE

(71) Applicant: HGST Netherlands B.V., Amsterdam (NL)

(72) Inventor: Aniryudh Reddy Durgam, San Diego, CA (US)

(21) Appl. No.: 14/601,954

(22) Filed: Jan. 21, 2015

(51) Int. Cl. G11C 16/08; G11C 16/26

(52) U.S. Cl. CPC G11C 16/08; G11C 16/26

(57) ABSTRACT

A method includes reading, by a controller of a storage device, bits from a reserved word line of a block in a memory of the storage device; identifying, by the controller and based on the bits read from the reserved word line, one or more bit lines of a plurality of bit lines of the block that include at least one stuck memory cell; reading, by the controller, a page of data from the block; and decoding, by the controller and based on the identified one of more bit lines of the block that include at least one stuck memory cell, the page of data read from the block.

### TECHNICAL FIELD

This disclosure relates to performance throttling, and more particularly, to selective enabling of performance throttling for solid state drives.

### BACKGROUND

Memory devices used in computers or other electronics devices may be non-volatile memory or volatile memory. The main difference between non-volatile memory and volatile memory is that non-volatile memory may continue to store data without requiring a persistent power supply. As a result, non-volatile memory devices have developed into a popular type of memory for a wide range of electronic applications. For instance, non-volatile memory devices, including flash memory devices, are commonly incorporated into solid-state storage devices, such as solid-state drives (SSDs).

### SUMMARY

In one example, a method includes reading, by a controller of a storage device, bits from a reserved word line of a block in a memory of the storage device; identifying, by the controller and based on the bits read from the reserved word line, one or more bit lines of a plurality of bit lines of the block that include at least one stuck memory cell; reading, by the controller, a page of data from the block; and decoding, by the controller and based on the identified one of more bit lines of the block that include at least one stuck memory cell, the page of data read from the block.

In another example, a data storage device includes a non-volatile memory, and a controller. In this example, the controller is configured to: read bits from a reserved word line of a block in the memory; identify, based on the bits read from the reserved word line, one or more bit lines of a plurality of bit lines of the block that include at least one stuck memory cell; read a page of data from the block; and decode, based on the identified one of more bit lines of the block that include at least one stuck memory cell, the page of data read from the block.

In another example, a computer-readable storage medium stores instructions that, when executed, cause one or more processors of a data storage device to: read bits from a reserved word line of a block in a memory of the storage device; identify, based on the bits read from the reserved word line, one or more bit lines of a plurality of bit lines of the block that are in-error; read a page of data from the block; and decode, based on the identified one of more bit lines of the block that are in-error, the page of data read from the block.

In another example, a system includes means for reading bits from a reserved word line of a block in a memory of a storage device; means for identifying, based on the bits read from the reserved word line, one or more bit lines of a plurality of bit lines of the block that include at least one stuck memory cell; means for reading a page of data from the block; and means for decoding, based on the identified one of more bit lines of the block that include at least one stuck memory cell, the page of data read from the block.

The details of one or more examples are set forth in the accompanying drawings and the description below. Other features, objects, and advantages will be apparent from the description and drawings, and from the claims.

### BRIEF DESCRIPTION OF DRAWINGS

FIG. 1 is a conceptual and schematic block diagram illustrating an example storage environment in which a storage device may function as a storage device for a host device, in accordance with one or more techniques of this disclosure

FIG. 2 is a conceptual and schematic block diagram illustrating an example controller, in accordance with one or more techniques of this disclosure.

FIG. 3 is a graph illustrating exemplary signals of an example storage device, in accordance with one or more techniques of this disclosure.

FIG. 4 is a flow diagram illustrating an example technique for utilizing a reserved word line in a block of a memory device to decode data read from other word lines of the same block, in accordance with one or more techniques of this disclosure

### DETAILED DESCRIPTION

The disclosure describes a memory device that includes a controller that is configured to use a reserved word line in a block of a memory device to identify bit lines that are in-error (e.g., include at least one stuck memory cell). The controller then may use information regarding bit lines that are in-error decode data read from other word lines of the same block. For example, if the data read from another word line does not pass a parity check, the controller may switch a value of a bit from a bit line identified to be in-error then perform the parity check again. If the data passes the parity check, the controller may refrain from performing other error correcting code (ECC) operations on the read data. If the data does not pass the parity check, the controller may perform other ECC operations on the read data. In this way, the identification of bit lines that are in-error using the reserved word line may reduce an amount of time required to recover data that does not pass an initial parity check.

Some memory devices, such as semiconductor memory devices, may be partitioned into a plurality of blocks. Each of the blocks may include a plurality of memory cells arranged on a plurality of word lines and a plurality of bit lines. As a block is cycled (i.e., written to/programmed), errors may develop in one or more bits of the block. For instance, one or more of the memory cells may become stuck such that all memory cells on the same bit line as the stuck bit will always be read as one value (e.g., zero), regardless of the data actually stored. The bit line including the stuck memory cell may be referred to a stuck bit line. In some examples, a bit line may become stuck due to insufficient read pass voltage (i.e., the voltage level applied when reading data).

As a bit line includes a bit from each respective page in the block, a bit in one page/word line causing this type of error may also cause error in all other pages of the block. For instance, if a bit line becomes stuck in a block that includes 512 pages, in the worst case scenario the block may have 512 bits in-error. Further, if another bit line becomes stuck in the same block, another 512 bits may be in-error.

In some examples, a controller may address the problem of stuck bit lines to some extent by increasing the read pass voltage. However, while increasing the read pass voltage may correct some errors, the increased voltage levels may also corrupt other bits and reduce memory cell endurance.

In accordance with one or more techniques of this disclosure, a controller of a memory device may use a reserved word line in a block of a memory device to facilitate decoding data read from other word lines of the same block. In some examples, a reserved word line may be a word line of the plurality of word lines that is not cycled (i.e., not programmed or erased). By not cycling the reserved word line, the controller can reduce the probability that memory cells on the reserved word line will become stuck.

The controller may use the reserved word line to determine if any of the bit lines of the block are in-error. In some examples, a particular bit line may be considered in-error when a memory cell on the particular bit line becomes stuck. To determine if any of the bit lines are in-error, the controller may read bits from the reserved word line. As the memory cells of the reserved word line have a reduced probability of being stuck, the controller may compare the bits read from the reserved word line with expected values. As one example, if the expected value for a particular bit of the bits read from the reserved word line (e.g., one) matches the actual value for the particular bit of the bits read from the reserved word line (e.g., one), the controller may determine that the bit line corresponding to the particular bit is not in-error. As another example, if the expected value for a particular bit of the bits read from the reserved word line (e.g., one) does not match the actual value for the particular bit of the bits read from the reserved word line (e.g., zero), the controller may determine that the bit line corresponding to the particular bit is in-error.

The controller may read one or more pages of data from the block (i.e., data from other word lines of the block) and decode the one or more pages of data read from the block based at least in part on which bit lines were determined to be in-error. For instance, where the one or more pages of data are written using error correcting code (ECC), the controller may include an ECC decoder that will correct the bits on the bit lines determined to be in-error. In this way, a controller may compensate for stuck bit lines without sacrificing memory cell endurance.

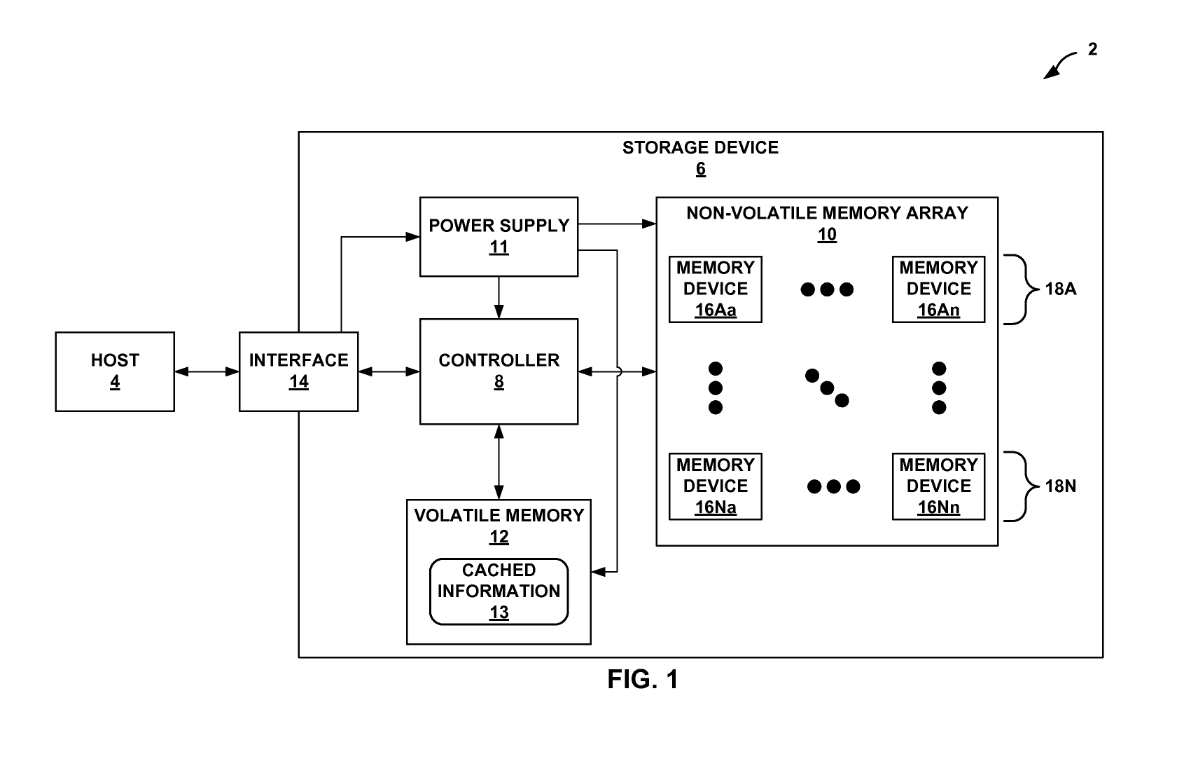

FIG. 1 is a conceptual and schematic block diagram illustrating an example storage environment 2 in which storage device 6 may function as a storage device for host device 4, in accordance with one or more techniques of this disclosure. For instance, host device 4 may utilize non-volatile memory devices included in storage device 6 to store and retrieve data. In some examples, storage environment 2 may include a plurality of storage devices, such as storage device 6, that may operate as a storage array. For instance, storage environment 2 may include a plurality of storages devices 6 configured as a redundant array of inexpensive/independent disks (RAID) that collectively function as a mass storage device for host device 4.

Storage environment 2 may include host device 4 which may store and/or retrieve data to and/or from one or more storage devices, such as storage device 6. As illustrated in FIG. 1, host device 4 may communicate with storage device 6 via interface 14. Host device 4 may comprise any of a wide range of devices, including computer servers, network attached storage (NAS) units, desktop computers, notebook (i.e., laptop) computers, tablet computers, set-top boxes, telephone handsets such as so-called “smart” phones, so-called “smart” pads, televisions, cameras, display devices, digital media players, video gaming consoles, video streaming device, and the like.

As illustrated in FIG. 1 storage device 6 may include controller 8, non-volatile memory array 10 (NVMA 10), power supply 11, volatile memory 12, and interface 14. In some examples, storage device 6 may include additional components not shown in FIG. 1 for sake of clarity. For example, storage device 6 may include a printed board (PB) to which components of storage device 6 are mechanically attached and which includes electrically conductive traces that electrically interconnect components of storage device 6; and the like. In some examples, the physical dimensions and connector configurations of storage device 6 may conform to one or more standard form factors. Some example standard form factors include, but are not limited to, 3.5″ hard disk drive (HDD), 2.5″ HDD, 1.8″ HDD, peripheral component interconnect (PCI), PCI-extended (PCI-X), PCI Express (PCIe) (e.g., PCIe x1, x4, x8, x16, PCIe Mini Card, MiniPCI, etc.). In some examples, storage device 6 may be directly coupled (e.g., directly soldered) to a motherboard of host device 4.

Storage device 6 may include interface 14 for interfacing with host device 4. Interface 14 may include one or both of a data bus for exchanging data with host device 4 and a control bus for exchanging commands with host device 4. Interface 14 may operate in accordance with any suitable protocol. For example, interface 14 may operate in accordance with one or more of the following protocols: advanced technology attachment (ATA) (e.g., serial-ATA (SATA) and parallel-ATA (PATA)), Fibre Channel, small computer system interface (SCSI), serially attached SCSI (SAS), peripheral component interconnect (PCI), and PCI-express. The electrical connection of interface 14 (e.g., the data bus, the control bus, or both) is electrically connected to controller 8, providing electrical connection between host device 4 and controller 8, allowing data to be exchanged between host device 4 and controller 8. In some examples, the electrical connection of interface 14 may also permit storage device 6 to receive power from host device 4. For example, as illustrated in FIG. 1, power supply 11 may receive power from host device 4 via interface 14.

Storage device 6 may include NVMA 10, which may include a plurality of memory devices 16Aa-16Nn (collectively, “memory devices 16”). Each of memory devices 16 may be configured to store and/or retrieve data. For instance, a memory device of memory devices 16 may receive data and a message from controller 8 that instructs the memory device to store the data. Similarly, the memory device of memory devices 16 may receive a message from controller 8 that instructs the memory device to retrieve data. In some examples, each of memory devices 6 may be referred to as a die. In some examples, a single physical chip may include a plurality of dies (i.e., a plurality of memory devices 16). In some examples, each of memory devices 16 may be configured to store relatively large amounts of data (e.g., 128 MB, 256 MB, 512 MB, 1 GB, 2 GB, 4 GB, 8 GB, 16 GB, 32 GB, 64 GB, 128 GB, 256 GB, 512 GB, 1 TB, etc.).

In some examples, memory devices 16 may include any type of non-volatile memory devices. Some examples, of memory devices 16 include, but are not limited to flash memory devices, phase-change memory (PCM) devices, resistive random-access memory (ReRAM) devices, magnetoresistive random-access memory (MRAM) devices, ferroelectric random-access memory (F-RAM), holographic memory devices, and any other type of non-volatile memory devices.

Flash memory devices may include NAND or NOR based flash memory devices, and may store data based on a charge contained in a floating gate of a transistor for each flash memory cell. In NAND flash memory devices, the flash memory device may be divided into a plurality of blocks which may divided into a plurality of pages. Each block of the plurality of blocks within a particular memory device may include a plurality of NAND cells. Rows of NAND cells may be electrically connected using a word line to define a page of a plurality of pages. Respective cells in each of the plurality of pages may be electrically connected to respective bit lines. Controller 6 may write data to and read data from NAND flash memory devices at the page level and erase data from NAND flash memory devices at the block level.

In some examples, it may not be practical for controller 8 to be separately connected to each memory device of memory devices 16. As such, the connections between memory devices 16 and controller 8 may be multiplexed. As an example, memory devices 16 may be grouped into channels 18A-18N (collectively, “channels 18”). For instance, as illustrated in FIG. 1, memory devices 16Aa-16Nn may be grouped into first channel 18A, and memory devices 16Na-16Nn may be grouped into N^{th} channel 18N. The memory devices 16 grouped into each of channels 18 may share one or more connections to controller 8. For instance, the memory devices 16 grouped into first channel 18A may be attached to a common I/O bus and a common control bus. Storage device 6 may include a common I/O bus and a common control bus for each respective channel of channels 18. In some examples, each channel of channels 18 may include a set of chip enable (CE) lines which may be used to multiplex memory devices on each channel. For example, each CE line may be connected to a respective memory device of memory devices 18. In this way, the number of separate connections between controller 8 and memory devices 18 may be reduced. Additionally, as each channel has an independent set of connections to controller 8, the reduction in connections may not significantly affect the data throughput rate as controller 8 may simultaneously issue different commands to each channel.

In some examples, storage device 6 may include a number of memory devices 16 selected to provide a total capacity that is greater than the capacity accessible to host device 4. This is referred to as over-provisioning. For example, if storage device 6 is advertised to include 240 GB of user-accessible storage capacity, storage device 6 may include sufficient memory devices 16 to give a total storage capacity of 256 GB. The 16 GB of storage devices 16 may not be accessible to host device 4 or a user of host device 4. Instead, the additional storage devices 16 may provide additional blocks to facilitate writes, garbage collection, wear leveling, and the like. Further, the additional storage devices 16 may provide additional blocks that may be used if some blocks wear to become unusable and are retired from use. The presence of the additional blocks may allow retiring of the worn blocks without causing a change in the storage capacity available to host device 4. In some examples, the amount of over-provisioning may be defined as p=(T−D)/D, wherein p is the over-provisioning ratio, T is the total storage capacity of storage device 2, and D is the storage capacity of storage device 2 that is accessible to host device 4.

Storage device 6 may include power supply 11, which may provide power to one or more components of storage device 6. When operating in a standard mode, power supply 11 may provide power to the one or more components using power provided by an external device, such as host device 4. For instance, power supply 11 may provide power to the one or more components using power received from host device 4 via interface 14. In some examples, power supply 11 may include one or more power storage components configured to provide power to the one or more components when operating in a shutdown mode, such as where power ceases to be received from the external device. In this way, power supply 11 may function as an onboard backup power source. Some examples of the one or more power storage components include, but are not limited to, capacitors, super capacitors, batteries, and the like. In some examples, the amount of power that may be stored by the one or more power storage components may be a function of the cost and/or the size (e.g., area/volume) of the one or more power storage components. In other words, as the amount of power stored by the one or more power storage components increases, the cost and/or the size of the one or more power storage components also increases.

Storage device 6 may include volatile memory 12, which may be used by controller 8 to store information. In some examples, controller 8 may use volatile memory 12 as a cache. For instance, controller 8 may store cached information 13 in volatile memory 12 until cached information 13 is written to memory devices 16. As illustrated in FIG. 1, volatile memory 12 may consume power received from power supply 11. Examples of volatile memory 12 include, but are not limited to, random-access memory (RAM), dynamic random access memory (DRAM), static RAM (SRAM), and synchronous dynamic RAM (SDRAM (e.g., DDR1, DDR2, DDR3, DDR3L, LPDDR3, DDR4, and the like).

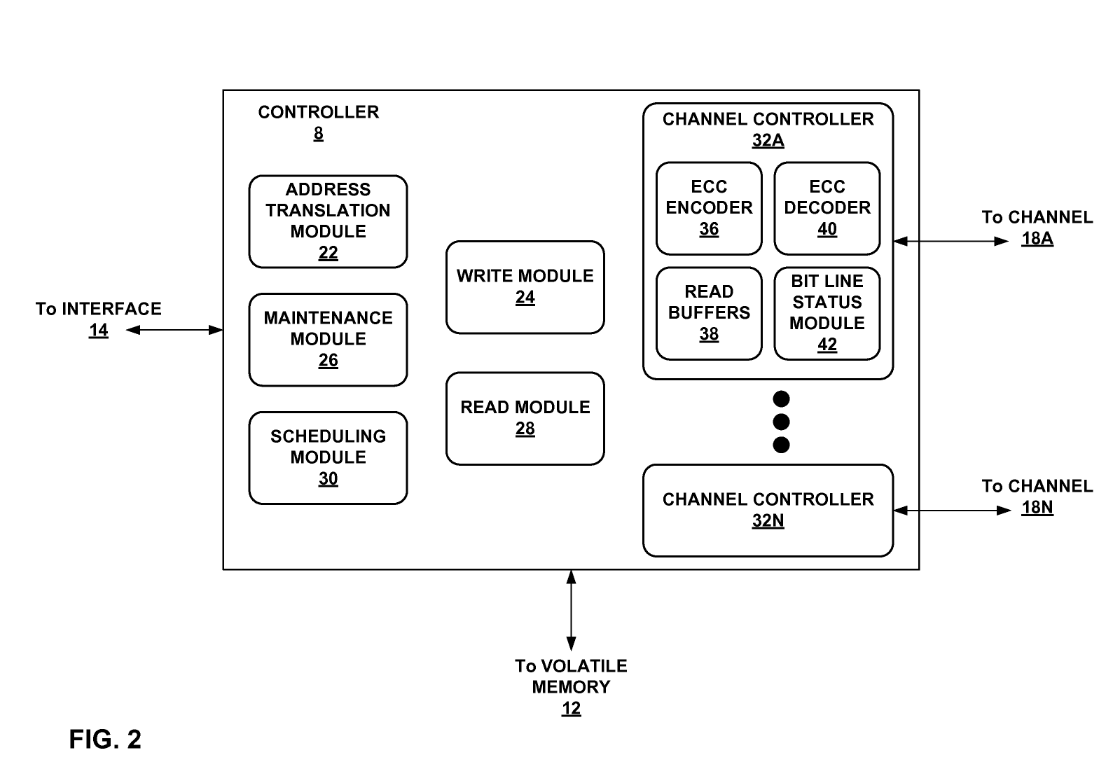

Storage device 6 includes controller 8, which may manage one or more operations of storage device 6. For instance, controller 8 may manage the reading of data from and/or the writing of data to memory devices 16. Additional details of controller 8 are discussed below with reference to FIG. 2.

In accordance with one or more techniques of this disclosure, controller 8 may utilize a reserved word line of a block of a memory device (e.g., a memory device of memory devices 16) to determine whether any bit lines in the block are in-error. For instance, controller 8 may read bits from a reserved word line of a block in a memory device of memory devices 16, and identify, based on the bits read from the reserved word line, one or more bit lines of a plurality of bit lines of the block that are in-error (e.g., include at least one stuck memory cell). Controller 8 may read a page of data from the block, and decode, based on the identified one of more bit lines of the block that are in-error, the page of data read from the block. For instance, controller 8 may flip the values of one or more bits of the page of data read from the block that correspond to the identified one of more bit lines of the block that are in-error. In this way, controller 8 may compensate for stuck bit lines without sacrificing endurance of memory cells within the block.

FIG. 2 is a conceptual and schematic block diagram illustrating example details of controller 8. In some examples, controller 8 may include an address translation module 22, a write module 24, a maintenance module 26, a read module 28, a scheduling module 30, and a plurality of channel controllers 32A-32N (collectively, “channel controllers 28”). In other examples, controller 8 may include additional modules or hardware units, or may include fewer modules or hardware units. Controller 8 may include a microprocessor, digital signal processor (DSP), application specific integrated circuit (ASIC), field programmable gate array (FPGA), or other digital logic circuitry. In some examples, controller 8 may be a system on a chip (SoC).

Controller 8 may interface with the host device 4 via interface 14 and manage the storage of data to and the retrieval of data from memory devices 16. For example, write module 24 of controller 8 may manage writes to memory devices 16. For example, write module 24 may receive a message from host device 4 via interface 14 instructing storage device 6 to store data associated with a logical address and the data. Write module 24 may manage writing of the data to memory devices 16.

For example, write module 24 may communicate with address translation module 22, which manages translation between logical addresses used by host device 4 to manage storage locations of data and physical block addresses used by write module 24 to direct writing of data to memory devices. Address translation module 22 of controller 8 may utilize a flash translation layer or table that translates logical addresses (or logical block addresses) of data stored by memory devices 16 to physical block addresses of data stored by memory devices 16. For example, host device 4 may utilize the logical block addresses of the data stored by memory devices 16 in instructions or messages to storage device 6, while write module 24 utilizes physical block addresses of the data to control writing of data to memory devices 16. (Similarly, read module 28 may utilize physical block addresses to control reading of data from memory devices 16.) The physical block addresses correspond to actual, physical blocks of memory devices 16. In some examples, address translation module 22 may store the flash translation layer or table in volatile memory 12, such as within cached information 13.

In this way, host device 4 may be allowed to use a static logical block address for a certain set of data, while the physical block address at which the data is actually stored may change. Address translation module 22 may maintain the flash translation layer or table to map the logical block addresses to physical block addresses to allow use of the static logical block address by the host device 4 while the physical block address of the data may change, e.g., due to wear leveling, garbage collection, or the like.

As discussed above, write module 24 of controller 8 may perform one or more operations to manage the writing of data to memory devices 16. For example, write module 24 may manage the writing of data to memory devices 16 by selecting one or more blocks within memory devices 16 to store the data and causing memory devices of memory devices 16 that include the selected blocks to actually store the data. As discussed above, write module 24 may cause address translation module 22 to update the flash translation layer or table based on the selected blocks. For instance, write module 24 may receive a message from host device 4 that includes a unit of data and a logical block address, select a block within a particular memory device of memory devices 16 to store the data, cause the particular memory device of memory devices 16 to actually store the data (e.g., via a channel controller of channel controllers 32 that corresponds to the particular memory device), and cause address translation module 22 to update the flash translation layer or table to indicate that the logical block address corresponds to the selected block within the particular memory device.

In some examples, in addition to causing the data to be stored by memory devices 16, write module 24 may cause memory devices 16 to store information which may be used to recover the unit of data should one or more of the blocks fail or become corrupted. The parity information may be used to recover the data stored by other blocks. In some examples, the parity information may be an XOR of the data stored by the other blocks.

In order to write a bit with a logical value of 0 (charged) to a bit with a previous logical value of 1 (uncharged), a large voltage is used. This voltage may be sufficiently large that it may cause inadvertent changes to the charge of adjacent flash memory cells. To protect against inadvertent changes, an entire block of flash memory cells may be erased to a logical value of 1 (uncharged) prior to writing any data to cells within the block. Because of this, flash memory cells may be erased at the block level and written at the page level.

Thus, to write and/or update even an amount of data that would consume less than one page, controller 8 may cause an entire block to be erased (e.g., if storage devices 16 contain no free blocks). This may lead to write amplification, which refers to the ratio between the amount of data received from host device 4 to be written to memory devices 16 and the amount of data actually written to memory devices 16. Write amplification contributes to faster wearing of the flash memory cells than would occur with no write amplification. Wear to flash memory cells may occur when flash memory cells are erased due to the relatively high voltages used to erase the flash memory cells. Over a plurality of erase cycles, the relatively high voltages may result in changes to the flash memory cells. Eventually, the flash memory cells may wear out, such that data may no longer be written to the cells.

One technique that controller 8 may implement to reduce write amplification and wear of flash memory cells includes writing data received from host device 4 to unused blocks or partially used blocks. For example, if host device 4 sends data to storage device 6 that includes only a small change from data already stored by storage device 6. The controller then may mark the old data as stale or no longer valid. Over time, this may reduce a number of erase operations blocks are exposed to, compared to erasing the block that holds the old data and writing the updated data to the same block.

Responsive to receiving a write command from host device 4, write module 24 may determine at which physical locations (e.g., blocks) of memory devices 16 to write the data. For example, write module 24 may request from address translation module 22 or maintenance module 26 one or more physical block addresses that are empty (e.g., store no data), partially empty (e.g., only some pages of the block store data), or store at least some invalid (or stale) data. Upon receiving the one or more physical block addresses, write module 24 may select one or more block as discussed above, and communicate a message that causes channel controllers 32A-32N (collectively, “channel controllers 32”) to write the data to the selected blocks.

Read module 28 similarly may control reading of data from memory devices 16. For example, read module 28 may receive a message from host device 4 requesting data with an associated logical block address. Address translation module 22 may convert the logical block address to a physical block address using the flash translation layer or table. Read module 28 then may control one or more of channel controllers 32 to retrieve the data from the physical block addresses. Similar to write module 24, read module 28 may select one or more blocks and communicate a message to that causes channel controllers 32 to read the data from the selected blocks.

Each channel controller of channel controllers 32 may be connected to a respective channel of channels 18. In some examples, controller 8 may include the same number of channel controllers 32 as the number of channels 18 of storage device 2. Channel controllers 32 may perform the intimate control of addressing, programming, erasing, and reading of memory devices 16 connected to respective channels, e.g., under control of write module 24, read module 28, and/or maintenance module 26.

Maintenance module 26 may be configured to perform operations related to maintaining performance and extending the useful life of storage device 6 (e.g., memory devices 16). For example, maintenance module 26 may implement at least one of wear leveling or garbage collection.

As described above, erasing flash memory cells may use relatively high voltages, which, over a plurality of erase operations, may cause changes to the flash memory cells. After a certain number of erase operations, flash memory cells may degrade to the extent that data no longer may be written to the flash memory cells, and a block including those cells may be retired (no longer used by controller 8 to store data). To increase the amount of data that may be written to memory devices 16 before blocks are worn and retired, maintenance module 26 may implement wear leveling.

In wear leveling, maintenance module 26 may track a number of erases of or writes to a block or a group of blocks, for each block or group of blocks. Maintenance module 26 may cause incoming data from host device 4 to be written to a block or group of blocks that has undergone relatively fewer writes or erases, to attempt to maintain the number of writes or erases for each block or group of blocks approximately equal. This may cause each block of memory devices 16 to wear out at approximately the same rate, and may increase the useful lifetime of storage device 6.

Although this may reduce write amplification and wear of flash memory cells by reducing a number of erases and writing data to different blocks, this also may lead to blocks including some valid (fresh) data and some invalid (stale) data. To combat this, maintenance module 26 may implement garbage collection. In a garbage collection operation, maintenance module 26 may analyze the contents of the blocks of memory devices 16 to determine a block that contain a high percentage of invalid (stale) data. Maintenance module 26 then may rewrite the valid data from the block to a different block, and then erase the block. This may reduce an amount of invalid (stale) data stored by memory devices 16 and increase a number of free blocks, but also may increase write amplification and wear of memory devices 16.

Scheduling module 30 of controller 8 may schedule operations to be performed by memory devices 16. For instance, scheduling module 30 may cause one or more of memory devices 16 to perform one or more operations based on requests received from other components of controller 8. In some examples, scheduling module 30 may cause a particular memory device of memory devices 16 to perform one or more operations by causing a channel controller corresponding to the particular memory device to output commands to the particular memory device. As one example, scheduling module 30 may permit channel controller 32A to output commands that cause memory device 16Aa to store data.

Furthermore, although shown only with respect to channel controller 32A for ease of illustration purposes, each of channel controllers 32 may include ECC encoder 36, read buffers 38, ECC decoder 40, and bit line status module 42 similar to that shown with respect to channel controller 32A. ECC encoder 36 may represent a unit or module configured to perform ECC encoding to data waiting to be written to non-volatile memory area 10. Read buffer 38 represent a unit or module configured to store data read from non-volatile memory area 10. ECC decoders 40 may represent units or modules configured to perform ECC decoding with respect to data stored to read buffer 38. In some examples, ECC encoder 36 and ECC decoder 40 may utilize low-density parity-check (LDPC) codes. Bit line status module 42 may be configured to identify whether any bit lines in a block are in-error.

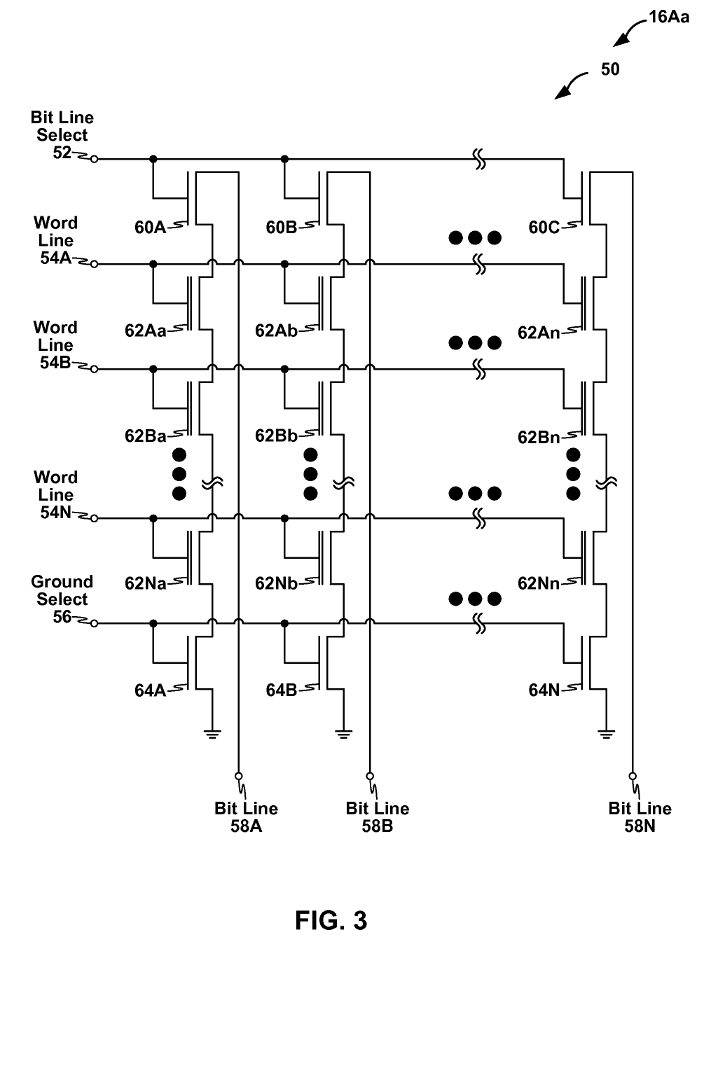

FIG. 3 is a conceptual and schematic block diagram illustrating example details of a block 50 of memory device 16Aa. As illustrated in FIG. 3, block 50 of memory device 16Aa may include bit line select transistors 60A-60C (collectively, “bit line select transistors 60”), memory cells 62Aa-62Nn (collectively, “memory cells 62”), and ground select transistors 64A-64C (collectively, “ground select transistors 64”).

In some examples, block 50 may include memory cells 62, which may each be configured to store one or more bits of data. In some examples, memory cells 62 may be non-volatile memory cells, such as floating gate transistors.

As discussed above, the memory cells of a block may be arranged into rows and columns respectively referred to as word lines and bit lines. As illustrated in FIG. 3, memory cells 62 are arranged into and electrically connected in word lines 54A-54N (collectively, “word lines 54”) and bit lines 58A-58N (collectively, “bit lines 58”). Memory cells 62Aa-62An may be considered to be on word line 54A because the gates of memory cells 62Aa-62An are commonly connected. Similarly, memory cells 62Ba-62Bn may be considered to be on word line 54B because the gates of memory cells 62Ba-62Bn are commonly connected. Memory cells 62Aa-62Na may be considered to be on bit line 58A because the sources and drains of memory cells 62Aa-62An are connected in series. Similarly, memory cells 62Ab-62Nb may be considered to be on bit line 58B because the sources and drains of memory cells 62Ab-62Ab are connected in series.

In some examples, block 50 may include bit line select transistors 60, which may be configured to selectively couple memory cells to bit lines. As one example, bit line select transistor 60A may selectively couple memory cells 62Aa-62Na to bit line 58A in response to a signal being applied to bit line select 52. As another example, bit line select transistor 60B may selectively couple memory cells 62Ab-62Nb to bit line 58B in response to a signal being applied to bit line select 52. In some examples, bit line select transistors 60 may be volatile. Some examples of bit line select transistors 60 include, but are not limited to, bipolar junction transistors (BJTs), junction gate field-effect transistor (JFET), metal-oxide semiconductor field-effect transistor (MOSFET), or any other suitable transistor.

In some examples, block 50 may include ground select transistors 64, which may be configured to selectively couple memory cells to ground. As one example, ground select transistor 64A may selectively couple memory cells 62Aa-62Na to ground in response to a signal being applied to ground select 56. As another example, ground select transistor 64B may selectively couple memory cells 62Ab-62Nb to ground in response to a signal being applied to ground select 56. In some examples, ground select transistors 64 may be volatile. Some examples of ground select transistors 64 include, but are not limited to, bipolar junction transistors (BJTs), junction gate field-effect transistor (JFET), metal-oxide semiconductor field-effect transistor (MOSFET), or any other suitable transistor.

As discussed above, a block is cycled (i.e., written to/programmed), errors may develop in one or more memory cells 62 of the block. For instance, as block 50 is cycles, one or more of memory cells 62 may become stuck such that bits read from corresponding bit line of bit lines 58 will always be one value (e.g., zero), regardless of the data actually stored in the memory cells 62 of the bit line. As one example, if memory cell 62Ab becomes stuck and memory cell 62Bb stores a one, when controller 8 reads the page of data on word line 54B, the bit read from bit line 58B may always be zero, even though the bit actually stored is one.

Referring now to FIGS. 2 and 3 and in accordance with one or more techniques of this disclosure, bit line status module 42 of channel controller 32A may determine whether any bit lines of bit lines 58 are in-error using a reserved word line. In some examples, bit line status module 42 may cause a word line to become a reserved word line by preventing the word line from being cycled (i.e., written to/programmed). By preventing a word line from being cycled, bit line status module 42 may reduce the probability that memory cells on the reserved word line will become stuck. For instance, where word line 54A is the reserved word line, bit line status module 42 may prevent memory cells 62Aa-62An from being cycled. In some examples, even though a reserved word line is not written to/programmed, large voltages may still be applied to the reserved word line. For instance, large voltages may be applied to a reserved word line when the block that includes the reserved word line is erased, as erasing may be performed at the block level.

While the operations are described below with word line 54A as the reserved word line, this disclosure is not so limited. For instance, any of word lines 54 may be used as a reserved word line. Furthermore, in some examples, as opposed to using a word line of word lines 54, bit line status module 42 may determine whether any bit lines of bit lines 58 are in-error using a virtual reserved word line. As one example, bit line status module 42 may use bit line select transistors 60 as a virtual word line. As another example, bit line status module 42 may use ground select transistors 64 as a virtual word line. In this way, bit line status module 42 may determine whether any bit lines of bit lines 58 are in-error without sacrificing storage space (i.e., without reducing the amount of data that may be stored in block 50).

In any case, bit line status module 42 may use reserved word line 54A to determine if any of bit lines 58 of block 50 are in-error. For instance, bit line status module 42 may receive bits read from reserved word line 54A. In some examples, each memory cell of reserved word line 54A may initially be a same value (e.g., a default value without being written to), which, for the purposes of this example, may be one. As the memory cells on word line 54A have not been cycled, the memory cells should all store the same value. However, if one or more of the memory cells on other word lines (i.e., memory cells 62Ba-62Nn) is stuck, the bit read from a corresponding bit line of bits lines 58 may be zero. For instance, if memory cell 62Na is stuck, the bits read at bit lines 58 when reading reserved word line 54A may be [0, 1, . . . , 1] whereas the bits “stored” in memory cells 62Aa-62An of reserved word line 54A may be [1, 1, . . . , 1].

Bit line status module 42 may identify, based on the bits read from reserved word line 54A, one or more of bit lines 58 that are in-error (e.g., include at least one stuck memory cell). For instance, bit line status module 42 may compare the bits read from reserved word line 54A (i.e., [0, 1, . . . , 1]) with bits expected to be read from reserved word line 54A (i.e., [1, 1, . . . , 1]). Where a value of a bit read from reserved word line 54A at particular bit line does not correspond to an expected value for the particular bit line, bit line status module 42 may determine that the particular bit line is in-error. To continue with the above example, bit line status module 42 may determine that bit line 58A is in-error because the value of the bit read from reserved word line 54A at bit line 58A (i.e., zero) does not correspond to an expected value for bit line 58A (i.e., one). Bit line status module 42 may output a list of the bit lines identified to be in-error to one or more components of controller 8, such as ECC decoder 40 of channel controller 32A which may use the list of the bit lines identified to be in-error to decode data from other word lines (i.e., other pages) of block 50.

Channel controller 32A may read a page of data from block 50. For instance, channel controller 32A may output commands to memory device 16Aa that cause memory device 16Aa to read the page of data stored at word line 54B of block 50 and provide the read data back to channel controller 32A, which may store the read data in read buffers 38.

ECC decoder 40 may decode, based on the identified one or more of bits lines 58 that are in-error, the page of data read from word line 54B. As the bit errors on reserved word line 54A may directly correlate to some fraction of bit errors (local bit errors on memory cells within word line 54B plus errors from stuck bit lines) from the page of data stored on word line 54B, ECC decoder 40 may correct bits of the data read from word line 54B corresponding to bit lines identified as in-error. For instance, where the page of data read from word line 54B includes parity data, ECC decoder 40 may decode the page of data read from word line 54B by comparing the bits of the page of data read from word line 54B with the parity data. If the bits of the page of data read from word line 54B correspond to the parity data, ECC decoder 40 may determine that the page of data read from word line 54B is successfully decoded.

If the bits of the page of data read from word line 54B do not correspond to the parity data, ECC decoder 40 may determine that the page of data read from word line 54B has not been successfully decoded. If the page of data read from word line 54B has not been successfully decoded, ECC decoder 40 may flip a bit of the page of data read from word line 54B on a bit line identified as in-error. ECC decoder 40 may determine whether the page of data read from word line 54B with the flipped bit correspond to the parity data. If the bits of the page of data read from word line 54B with the flipped bit correspond to the parity data, ECC decoder 40 may determine that the page of data read from word line 54B is successfully decoded with the flipped bit.

If the bits of the page of data read from word line 54B with the flipped bit do not correspond to the parity data, ECC decoder 40 may determine that the page of data read from word line 54B has not been successfully decoded with the flipped bit. If the page of data read from word line 54B has not been successfully decoded with the flipped bit and more than one bit line is identified as in-error, ECC decoder 40 may flip a bit of the page of data read from word line 54B on another bit line identified as in-error and determine whether the page of data read from word line 54B with the flipped bits correspond to the parity data. ECC decoder 40 may continue to iterate through combinations of flipped bits corresponding to bit lines identified in-error until the page of data read from word line 54B is successfully decoded. In this way, controller 8 may compensate for stuck bit lines.

However, if no combination of flipped bits causes the page of data read from word line 54B to be successfully decoded, ECC decoder 40 may use one or more other ECC techniques to attempt to decode the page of data read from word line 54B. For instance, ECC decoder 40 may use the parity data as opposed to bits from bit lines identified to be in-error. For example, where the page of data read from word line 54B includes an exclusive-or (XOR) parity bit stored by memory cell 62Bn and bit line 58A is identified to be in-error, ECC decoder 40 may decode the page of data read from word line 54B by using the XOR parity bit read from bit line 58N to determine the value of the bit stored by memory cell 62Ba. Also in this way, controller 8 may compensate for stuck bit lines.

In some examples, as opposed to identifying one or more bit lines in a block that are in-error before attempting to read pages of data from the block, ECC decoder 40 may identify one or more bit lines in the block that are in-error in response to determining that a page of data from the block is not successfully decoded. As discussed above, ECC decoder 40 may determine that a page of data is not successfully decoded if the page of data does not correspond to its parity data.

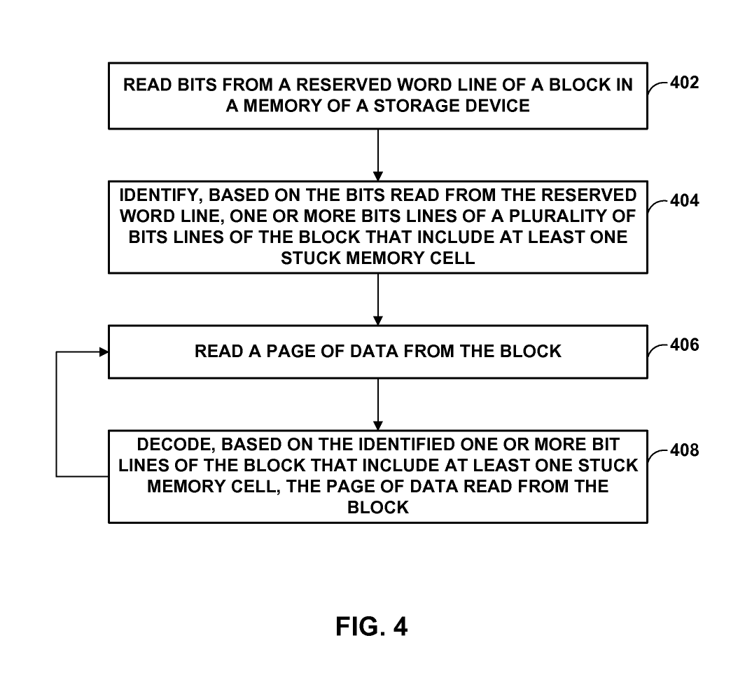

FIG. 4 is a flow diagram illustrating an example technique for utilizing a reserved word line in a block of a memory device to decode data read from other word lines of the same block, in accordance with one or more techniques of this disclosure. The techniques of FIG. 4 will be described with concurrent reference to storage device 6 of FIG. 1 and controller 8 of FIG. 1 and FIG. 2 for ease of description, although storage devices having configurations different than that of storage device 6, and controller 8 may perform the techniques of FIG. 4.

In accordance with one or more techniques of this disclosure, controller 8 of storage device 6 may read bits from a reserved word line of a block in a memory device (402). For instance, channel controller 32A of controller 8 may read bits from word line 54A of block 50 of memory device 16Aa of memory devices 16.

Controller 8 may identify, based on the bits read from the reserved word line, one or more bit lines of a plurality of bit lines of the block that are in-error (e.g., include at least one stuck memory cell) (404). For instance, bit line status module 42 of channel controller 32A may compare bits read from reserved word line 54A with bits expected to be read from reserved word line 54A. Where a value of a bit read from reserved word line 54A at particular bit line does not correspond to the expected value for the particular bit line, bit line status module 42 may determine that the particular bit line is in-error.

Controller 8 may read a page of data from the block (406). For instance, channel controller 32A may output commands to memory device 16Aa that cause memory device 16Aa to read the page of data stored at word line 54B of block 50 and provide the read data back to channel controller 32A, which may store the read data in read buffers 38.

Controller 8 may decode, based on the identified one or more bit lines of the block that are in-error, the page of data read from the block (408). For instance, ECC decoder 40 may decode the page of data read from word line 54B by comparing the bits of the page of data read from word line 54B with parity data for word line 54B. If the bits of the page of data read from word line 54B correspond to the parity data, ECC decoder 40 may determine that the page of data read from word line 54B is successfully decoded.

If the bits of the page of data read from word line 54B do not correspond to the parity data, ECC decoder 40 may determine that the page of data read from word line 54B has not been successfully decoded. If the page of data read from word line 54B has not been successfully decoded, ECC decoder 40 may flip a bit of the page of data read from word line 54B on a bit line identified as in-error. ECC decoder 40 may determine whether the page of data read from word line 54B with the flipped bit correspond to the parity data. If the bits of the page of data read from word line 54B with the flipped bit correspond to the parity data, ECC decoder 40 may determine that the page of data read from word line 54B is successfully decoded with the flipped bit.

If the bits of the page of data read from word line 54B with the flipped bit do not correspond to the parity data, ECC decoder 40 may determine that the page of data read from word line 54B has not been successfully decoded with the flipped bit. If the page of data read from word line 54B has not been successfully decoded with the flipped bit and more than one bit line is identified as in-error, ECC decoder 40 may flip a bit of the page of data read from word line 54B on another bit line identified as in-error and determine whether the page of data read from word line 54B with the flipped bits correspond to the parity data. In some examples, ECC decoder 40 may continue to iterate through combinations of flipped bits corresponding to bit lines identified in-error until the page of data read from word line 54B is successfully decoded.

However, if no combination of flipped bits causes the page of data read from word line 54B to be successfully decoded, ECC decoder 40 may use one or more other ECC techniques or other decoding techniques to attempt to decode the page of data read from word line 54B. For instance, ECC decoder 40 may use the parity data as opposed to bits from bit lines identified to be in-error. For example, where the page of data read from word line 54B includes an exclusive-or (XOR) parity bit stored by memory cell 62Bn and bit line 58A is identified to be in-error, ECC decoder 40 may decode the page of data read from word line 54B by using the XOR parity bit read from bit line 58N to determine the value of the bit stored by memory cell 62Ba.

In some examples, controller 8 may decode a plurality of pages from the same block based on the identified one or more bit lines of the block that are in-error. For instance, controller 8 may read another page of data from the block (406), and decode the other page of data based on the identified one or more bit lines of the block that are in-error. In this way, controller 8 may decode multiple pages using a single read of the reserved word line.

The following examples may illustrate one or more of the techniques of this disclosure.

### Example 1

A method comprising: reading, by a controller of a storage device, bits from a reserved word line of a block in a memory of the storage device; identifying, by the controller and based on the bits read from the reserved word line, one or more bit lines of a plurality of bit lines of the block that include at least one stuck memory cell; reading, by the controller, a page of data from the block; and decoding, by the controller and based on the identified one of more bit lines of the block that include at least one stuck memory cell, the page of data read from the block.

### Example 2

The method of example 1, wherein identifying the one or more bit lines that include at least one stuck memory cell comprises identifying whether a particular bit line of the plurality of bit lines includes at least one stuck memory cell by at least: determining that the particular bit line includes at least one stuck memory cell where a value of a bit read from the reserved word line that corresponds to the particular bit line does not correspond to an expected value for the particular bit line.

### Example 3

The method of any combination of examples 1-2, wherein data is not written to the reserved word line.

### Example 4

The method of any combination of examples 1-2, wherein the reserved word line includes a plurality non-volatile memory cells of the block.

### Example 5

The method of any combination of examples 1-2, wherein the reserved word line includes select transistors of the block.

### Example 6

The method of any combination of examples 1-5, wherein decoding the page of data read from the block comprises: responsive to determining that the page of data does not correspond to parity data for the page of data, flipping a bit included the page of data that corresponds to a bit line of the identified one or more bit lines of the block that include at least one stuck memory cell.

### Example 7

The method of any combination of examples 1-6, wherein flipping the bit comprises flipping a first bit included in the page of data that corresponds to a first bit line of the identified one or more bit lines of the block that include at least one stuck memory cell, the method further comprising: responsive to determining that the page of data with the first flipped bit does not correspond to the parity data for the page of data, flipping a second bit included the page of data that corresponds to a second bit line of the identified one or more bit lines of the block that include at least one stuck memory cell.

### Example 8

The method of any combination of examples 1-7, wherein: the bits from the reserved word line of the block are read in response to determining that the page of data does not correspond to parity data for the page of data, and the one or more bit lines of the plurality of bit lines of the block that include at least one stuck memory cell are identified in response to determining that the page of data does not correspond to parity data for the page of data.

### Example 9

The method of any combination of examples 1-8, further comprising: reading, by the controller, a plurality of pages of data from the block; decoding, by the controller and based on the identified one of more bit lines of the block that include at least one stuck memory cell, the plurality of pages of data read from the block.

### Example 10

A data storage device comprising: a memory; and a controller configured to: read bits from a reserved word line of a block in the memory; identify, based on the bits read from the reserved word line, one or more bit lines of a plurality of bit lines of the block that include at least one stuck memory cell; read a page of data from the block; and decode, based on the identified one of more bit lines of the block that include at least one stuck memory cell, the page of data read from the block.

### Example 11

The data storage device of example 10, wherein, to identify the one or more bit lines that include at least one stuck memory cell, the controller is configured to identify whether a particular bit line of the plurality of bit lines includes at least one stuck memory cell by at least: determining that the particular bit line includes at least one stuck memory cell where a value of a bit read from the reserved word line that corresponds to the particular bit line does not correspond to an expected value for the particular bit line.

### Example 12

The data storage device of any combination of examples 10-11, wherein data is not written to the reserved word line.

### Example 13

The data storage device of any combination of examples 10-12, wherein the reserved word line includes a plurality non-volatile memory cells of the block.

### Example 14

The data storage device of any combination of examples 10-12, wherein the reserved word line includes select transistors of the block.

### Example 15

The data storage device of any combination of examples 10-14, wherein the controller is configured to decode the page of data read from the block by at least: flipping a bit included the page of data that corresponds to a bit line of the identified one or more bit lines of the block that include at least one stuck memory cell in response to determining that the page of data does not correspond to parity data for the page of data.

### Example 16

The data storage device of any combination of examples 10-15, wherein the controller is configured to flip the bit by at least flipping a first bit included in the page of data that corresponds to a first bit line of the identified one or more bit lines of the block that include at least one stuck memory cell, and wherein the controller is further configured to: flip a second bit included the page of data that corresponds to a second bit line of the identified one or more bit lines of the block that include at least one stuck memory cell in response to determining that the page of data with the first flipped bit does not correspond to the parity data for the page of data.

### Example 17

The data storage device of any combination of examples 10-16, wherein the controller is configured to: read the bits from the reserved word line of the block in response to determining that the page of data does not correspond to parity data for the page of data, and identify the one or more bit lines of the plurality of bit lines of the block that include at least one stuck memory cell in response to determining that the page of data does not correspond to parity data for the page of data.

### Example 18

The data storage device of any combination of examples 10-17, wherein the controller is further configured to: read a plurality of pages of data from the block; decode, and based on the identified one of more bit lines of the block that include at least one stuck memory cell, the plurality of pages of data read from the block.

### Example 19

A system comprising: means for reading bits from a reserved word line of a block in a memory of a storage device; means for identifying, based on the bits read from the reserved word line, one or more bit lines of a plurality of bit lines of the block that include at least one stuck memory cell; means for reading a page of data from the block; and means for decoding, based on the identified one of more bit lines of the block that include at least one stuck memory cell, the page of data read from the block.

### Example 20

The system of example 19, further comprising means for performing any combination of the method of examples 1-9.

### Example 21

A computer-readable storage medium storing instructions that, when executed, cause a controller of a storage device to: read bits from a reserved word line of a block in a memory of the storage device; identify, based on the bits read from the reserved word line, one or more bit lines of a plurality of bit lines of the block that are in-error; read a page of data from the block; and decode, based on the identified one of more bit lines of the block that are in-error, the page of data read from the block.

### Example 22

The computer-readable storage medium of example 21, further storing instructions that, when executed, cause the controller to perform any combination of the method of examples 1-9.

The techniques described in this disclosure may be implemented, at least in part, in hardware, software, firmware, or any combination thereof. For example, various aspects of the described techniques may be implemented within one or more processors, including one or more microprocessors, digital signal processors (DSPs), application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry, alone or in combination with other logic circuitry, or any other equivalent circuitry. A control unit including hardware may also perform one or more of the techniques of this disclosure.

Such hardware, software, and firmware may be implemented within the same device or within separate devices to support the various techniques described in this disclosure. In addition, any of the described units, modules or components may be implemented together or separately as discrete but interoperable logic devices. Depiction of different features as modules or units is intended to highlight different functional aspects and does not necessarily imply that such modules or units must be realized by separate hardware, firmware, or software components. Rather, functionality associated with one or more modules or units may be performed by separate hardware, firmware, or software components, or integrated within common or separate hardware, firmware, or software components.

The techniques described in this disclosure may also be embodied or encoded in an article of manufacture including a computer-readable storage medium encoded with instructions. Instructions embedded or encoded in an article of manufacture including a computer-readable storage medium encoded, may cause one or more programmable processors, or other processors, to implement one or more of the techniques described herein, such as when instructions included or encoded in the computer-readable storage medium are executed by the one or more processors. Computer readable storage media may include random access memory (RAM), read only memory (ROM), programmable read only memory (PROM), erasable programmable read only memory (EPROM), electronically erasable programmable read only memory (EEPROM), flash memory, a hard disk, a compact disc ROM (CD-ROM), a floppy disk, a cassette, magnetic media, optical media, or other computer readable media. In some examples, an article of manufacture may include one or more computer-readable storage media.

In some examples, a computer-readable storage medium may include a non-transitory medium. The term “non-transitory” may indicate that the storage medium is not embodied in a carrier wave or a propagated signal. In certain examples, a non-transitory storage medium may store data that can, over time, change (e.g., in RAM or cache).

Various examples have been described. These and other examples are within the scope of the following claims.

What is claimed is:

1. A method comprising:
reading, by a controller of a storage device, bits from a reserved word line of a block in a memory of the storage device;
identifying, by the controller and based on the bits read from the reserved word line, one or more bit lines of a plurality of bit lines of the block that include at least one stuck memory cell;
reading, by the controller, a page of data from the block; and
decoding, by the controller and based on the identified one of more bit lines of the block that include at least one stuck memory cell, the page of data read from the block.

2. The method of claim 1, wherein identifying the one or more bit lines that include at least one stuck memory cell comprises identifying whether a particular bit line of the plurality of bit lines includes at least one stuck memory cell by at least:
determining that the particular bit line includes at least one stuck memory cell where a value of a bit read from the reserved word line that corresponds to the particular bit line does not correspond to an expected value for the particular bit line.

3. The method of claim 1, wherein data is not written to the reserved word line.

4. The method of claim 1, wherein the reserved word line includes a plurality non-volatile memory cells of the block.

5. The method of claim 1, wherein the reserved word line includes select transistors of the block.

6. The method of claim 1, wherein decoding the page of data read from the block comprises:
responsive to determining that the page of data does not correspond to parity data for the page of data, flipping a bit included the page of data that corresponds to a bit line of the identified one or more bit lines of the block that include at least one stuck memory cell.

7. The method of claim 6, wherein flipping the bit comprises flipping a first bit included in the page of data that corresponds to a first bit line of the identified one or more bit lines of the block that include at least one stuck memory cell, the method further comprising:
responsive to determining that the page of data with the first flipped bit does not correspond to the parity data for the page of data, flipping a second bit included the page of data that corresponds to a second bit line of the identified one or more bit lines of the block that include at least one stuck memory cell.

8. The method of claim 1, wherein:
the bits from the reserved word line of the block are read in response to determining that the page of data does not correspond to parity data for the page of data, and
the one or more bit lines of the plurality of bit lines of the block that include at least one stuck memory cell are identified in response to determining that the page of data does not correspond to parity data for the page of data.

9. The method of claim 1, further comprising:
reading, by the controller, a plurality of pages of data from the block;
decoding, by the controller and based on the identified one of more bit lines of the block that include at least one stuck memory cell, the plurality of pages of data read from the block.

10. A data storage device comprising:
a memory; and
a controller configured to:
read bits from a reserved word line of a block in the memory;
identify, based on the bits read from the reserved word line, one or more bit lines of a plurality of bit lines of the block that include at least one stuck memory cell;
read a page of data from the block; and
decode, based on the identified one of more bit lines of the block that include at least one stuck memory cell, the page of data read from the block.

11. The data storage device of claim 10, wherein, to identify the one or more bit lines that include at least one stuck memory cell, the controller is configured to identify whether a particular bit line of the plurality of bit lines includes at least one stuck memory cell by at least:
determining that the particular bit line includes at least one stuck memory cell where a value of a bit read from the reserved word line that corresponds to the particular bit line does not correspond to an expected value for the particular bit line.

12. The data storage device of claim 10, wherein data is not written to the reserved word line.

13. The data storage device of claim 10, wherein the reserved word line includes a plurality non-volatile memory cells of the block.

14. The data storage device of claim 10, wherein the reserved word line includes select transistors of the block.

15. The data storage device of claim 10, wherein the controller is configured to decode the page of data read from the block by at least:
flipping a bit included the page of data that corresponds to a bit line of the identified one or more bit lines of the block that include at least one stuck memory cell in response to determining that the page of data does not correspond to parity data for the page of data.

16. The data storage device of claim 15, wherein the controller is configured to flip the bit by at least flipping a first bit included in the page of data that corresponds to a first bit line of the identified one or more bit lines of the block that include at least one stuck memory cell, and wherein the controller is further configured to:
flip a second bit included the page of data that corresponds to a second bit line of the identified one or more bit lines of the block that include at least one stuck memory cell in response to determining that the page of data with the first flipped bit does not correspond to the parity data for the page of data.

17. The data storage device of claim 10, wherein the controller is configured to:
read the bits from the reserved word line of the block in response to determining that the page of data does not correspond to parity data for the page of data, and
identify the one or more bit lines of the plurality of bit lines of the block that include at least one stuck memory cell in response to determining that the page of data does not correspond to parity data for the page of data.

18. The data storage device of claim 10, wherein the controller is further configured to:
read a plurality of pages of data from the block;
decode, and based on the identified one of more bit lines of the block that include at least one stuck memory cell, the plurality of pages of data read from the block.

19. A system comprising:
means for reading bits from a reserved word line of a block in a memory of a storage device;
means for identifying, based on the bits read from the reserved word line, one or more bit lines of a plurality of bit lines of the block that include at least one stuck memory cell;
means for reading a page of data from the block; and
means for decoding, based on the identified one of more bit lines of the block that include at least one stuck memory cell, the page of data read from the block.

20. A computer-readable storage medium storing instructions that, when executed, cause a controller of a storage device to:
read bits from a reserved word line of a block in a memory of the storage device;
identify, based on the bits read from the reserved word line, one or more bit lines of a plurality of bit lines of the block that are in-error;
read a page of data from the block; and
decode, based on the identified one of more bit lines of the block that are in-error, the page of data read from the block.
